(19) United States
(12) Patent Application Publication
(10) Pub. No.: US 2014/0134774 A1
(43) Pub. Date: May 15, 2014

(54) METHOD FOR MAKING LIGHT EMITTING DIODE CHIP

(71) Applicant: ADVANCED OPTOELECTRONIC TECHNOLOGY, INC., Hsinchu Hsien (TW)

(72) Inventors: CHING-HSUEH CHIU, Hsinchu (TW); YA-WEN LIN, Hsinchu (TW); PO-MIN TU, Hsinchu (TW); SHIH-CHENG HUANG, Hsinchu (TW)

(73) Assignee: ADVANCED OPTOELECTRONIC TECHNOLOGY, INC., Hsinchu Hsien (TW)

(21) Appl. No.: 14/014,375

(22) Filed: Aug. 30, 2013

(30) Foreign Application Priority Data
Nov. 12, 2012 (CN) 2012104497866

(51) Int. Cl. H01L 33/24

(52) U.S. Cl. CPC H01L 33/24
USPC 438/47

(57) ABSTRACT

A method for making a light emitting diode chip includes following steps: providing a sapphire substrate, the sapphire substrate having a plurality of protrusions on an upper surface thereof; forming an un-doped GaN layer on the upper surface of the sapphire substrate, the un-doped GaN layer partly covering the protrusions to expose a part of each of the protrusions; etching the un-doped GaN layer to expose a top end of each of the protrusions; and forming an n-type GaN layer, an active layer, and a p-type GaN layer sequentially on the top ends of the protrusions and the un-doped GaN layer.

### BACKGROUND

1. Technical Field

The disclosure generally relates to a method for making a light emitting diode chip, wherein the light emitting diode chip can have less lattice defects and improved light extraction efficiency.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

In epitaxial growth of an LED chip, one problem is how to reduce lattice defects in the semiconductor layers. One way to reduce the lattice defects is to provide a pattered sapphire substrate. By forming a plurality of protrusions on the sapphire substrate, semiconductor layers will be laterally grown from the protrusions, thereby reducing the lattice defects in the semiconductor layers. However, the lattice defects are easy to concentrate on a top side of the protrusions to affect growth of following semiconductor layers.

What is needed, therefore, is a method for making the LED chip to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 shows a first step of a method for making an LED chip in accordance with an embodiment of the present disclosure.

FIG. 2 shows a second step of the method for making an LED chip in accordance with an embodiment of the present disclosure.

FIG. 3 shows a third step of the method for making an LED chip in accordance with an embodiment of the present disclosure.

FIG. 4 shows a fourth step of the method for making an LED chip in accordance with an embodiment of the present disclosure.

FIG. 5 shows a fifth step of the method for making an LED chip in accordance with an embodiment of the present disclosure.

### DETAILED DESCRIPTION

An embodiment of a method for making the LED chip will now be described in detail below and with reference to the drawings.

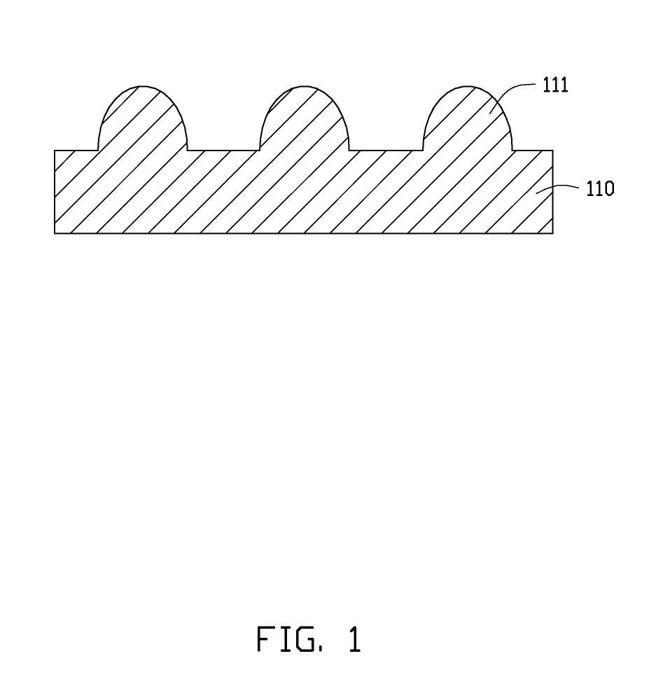

Referring to FIG. 1, a sapphire substrate 110 with a plurality of protrusions 111 is provided. A cross section of the sapphire substrate 110 is rectangular. The sapphire substrate 110 has an upper surface and a bottom surface opposite to the upper surface. The protrusions 111 are formed on the upper surface of the sapphire substrate 110. In this embodiment, each protrusion 111 has a semi-circular cross section. In alternative embodiments, the cross section of each of the protrusions 111 can be triangular, trapezoid, or other polygons.

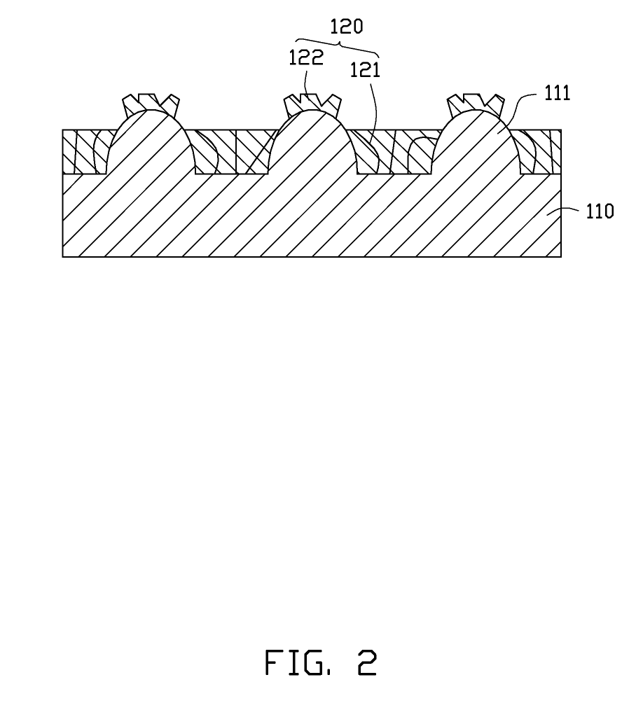

Referring to FIG. 2, an un-doped GaN layer 120 is formed on the upper surface of the sapphire substrate 110 having the protrusions 111. The un-doped GaN layer 120 partly covers the protrusions 111 to expose parts of the protrusions 111. In this embodiment, the un-doped GaN layer 120 includes a first portion 121 located between two protrusions 111 and a second portion 122 located on a top end of each of the protrusions 111.

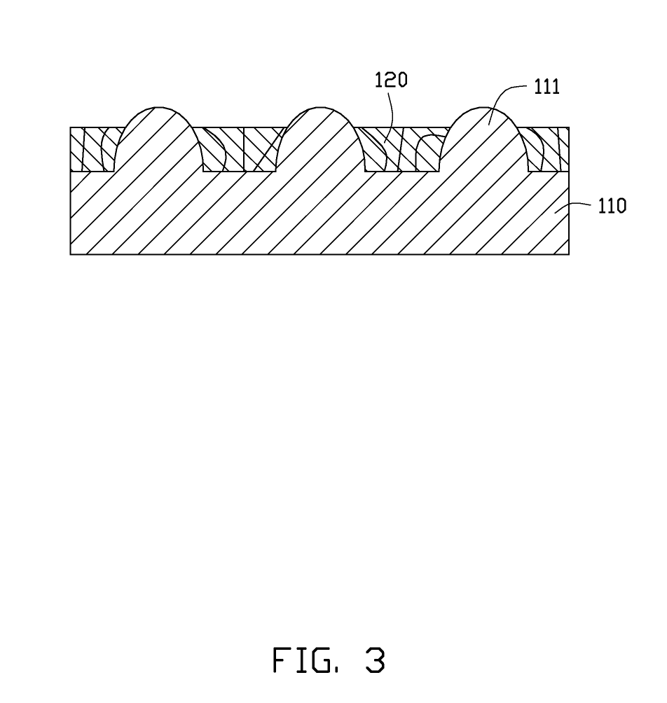

Referring to FIG. 3, the un-doped GaN layer 120 is etched to expose the top ends of the protrusions 111. The un-doped GaN layer 120 can be etched by wet etching process or by dry etching process. In this embodiment, the un-doped GaN layer 120 is etched by inductively coupled plasma etching. Preferably, the second portion 122 of the un-doped GaN layer 120 is totally etched away by the etching process to wholly expose the top ends of the protrusions 111.

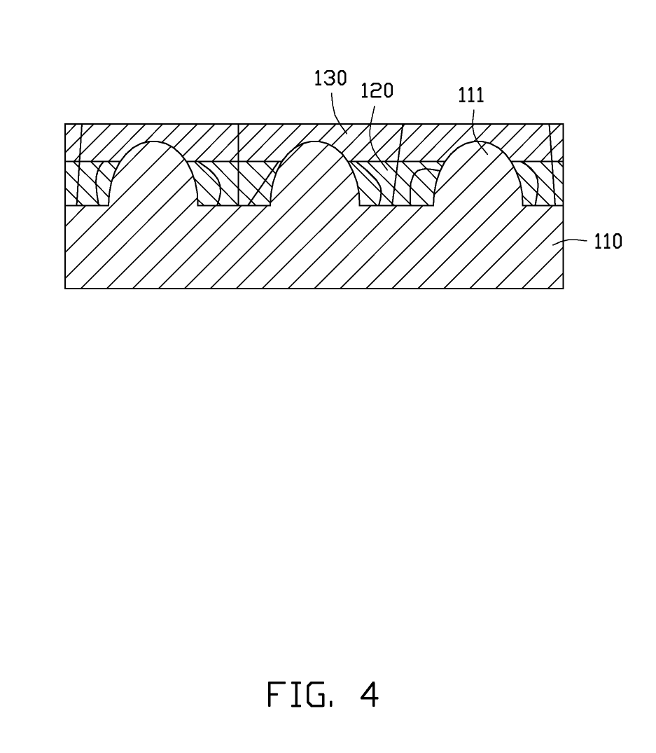

Referring to FIG. 4, a second un-doped GaN layer 130 is formed on the top ends of the protrusions 111 and the un-doped GaN layer 120.

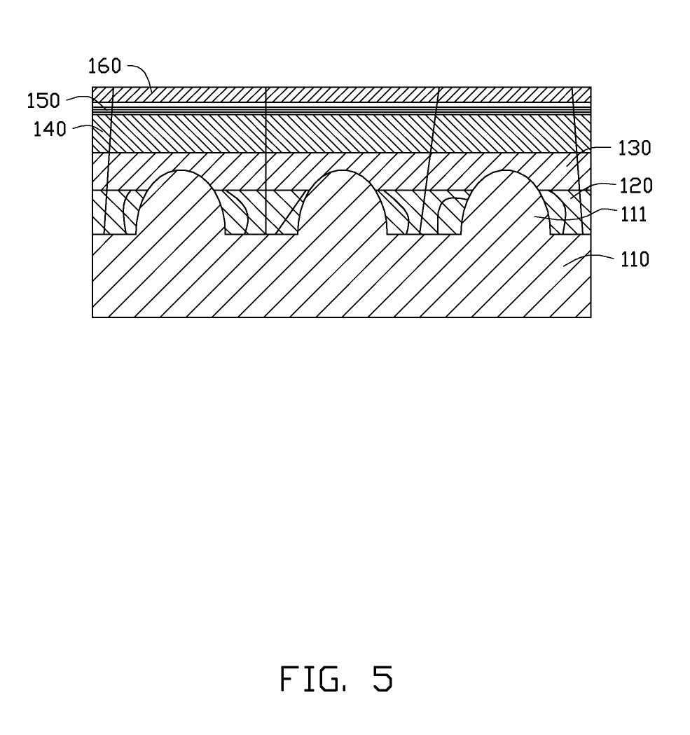

Referring to FIG. 5, an n-type GaN layer 140, an active layer 150, and a p-type GaN layer 160 are sequentially formed on the second un-doped GaN layer 130. In this embodiment, the active layer 150 is multiple quantum well (MQW) layer. In an alternative embodiment, the n-type GaN layer 140, the active layer 150, and the p-type GaN layer 160 can be directly formed on the top ends of the protrusions 111 and the un-doped GaN layer 120.

In the method for making an LED chip described above, the second portion 122 of the un-doped GaN layer 120 is etched away. Since lattice defects will concentrate on the second portion 122 of the un-doped GaN layer 120, the removing of the second portion 122 of the un-doped GaN layer 120 will prevent the lattice defects in the second portion 122 of the un-doped GaN layer 120 from extending upwardly into the n-type GaN layer 140, the active layer 150, and the p-type GaN layer 160. Therefore, the lattice qualities of the n-type GaN layer 140, the active layer 150, and the p-type GaN layer 160 are improved.

Preferably, in forming of the un-doped GaN layer 120, the un-doped GaN layer 120 can be epitaxial grown to totally cover the top ends of the protrusions 111. After that, the un-doped GaN layer 120 can be etched to expose the top ends of the protrusions 111. After the top ends of the protrusions 111 are exposed, the un-doped GaN layer 120 are continuously etched until a height of the un-doped GaN layer 120 is less than a height of each of the protrusions 111.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for making a light emitting diode chip, comprising:
providing a sapphire substrate, the sapphire substrate having a plurality of protrusions on an upper surface thereof;
forming an un-doped GaN layer on the upper surface of the sapphire substrate, the un-doped GaN layer partly covering the protrusions to expose a part of each of the protrusions;
etching the un-doped GaN layer to expose a top end of each of the protrusions; and
forming an n-type GaN layer, an active layer, and a p-type GaN layer sequentially on the top ends of the protrusions and the un-doped GaN layer.

2. The method of claim 1, wherein the un-doped GaN layer is etched by dry etching or wet etching.

3. The method of claim 2, wherein the un-doped GaN layer is etched by inductively coupled plasma etching.

4. The method of claim 1, wherein the active layer is a multiple quantum well layer.

5. The method of claim 1, wherein the protrusions each have a semi-circular, triangular or trapezoid cross section.

6. The method of claim 1, wherein the un-doped GaN layer comprises a first portion and a second portion, the first portion is located between two adjacent protrusions, the second portion is located on the top ends of the protrusions, and the second portion of the un-doped GaN layer is totally etched away after the etching of the un-doped GaN layer.

7. The method of claim 1, wherein before forming the n-type GaN layer on the top ends of the protrusions and the un-doped GaN layer, an additional un-doped GaN layer is formed on the top ends of the protrusions and the un-doped GaN layer, and then the n-type GaN layer, the active layer, and the p-type GaN layer are sequentially formed on the additional un-doped GaN layer.

8. A method for making a light emitting diode chip, comprising:
providing a sapphire substrate, the sapphire substrate having a plurality of protrusions on an upper surface thereof;
forming an un-doped GaN layer on the upper surface of the sapphire substrate until the un-doped GaN layer totally covering the protrusions;
etching the un-doped GaN layer to expose a top end of each of the protrusions; and
forming an n-type GaN layer, an active layer, and a p-type GaN layer sequentially on the top ends of the protrusions and the un-doped GaN layer.

9. The method of claim 8, wherein the un-doped GaN layer is etched by dry etching or wet etching.

10. The method of claim 9, wherein the un-doped GaN layer is etched by inductively coupled plasma etching.

11. The method of claim 8, wherein the active layer is a multiple quantum well layer.

12. The method of claim 8, wherein the protrusions each have a semi-circular, triangular or trapezoid cross section.

13. The method of claim 8, wherein the un-doped GaN layer comprises a first portion and a second portion, the first portion is located between two adjacent protrusions, the second portion is located on the upper end of each of the protrusions, the second portion of the un-doped GaN layer is totally etched away after the etching of the un-doped GaN layer.

14. The method of claim 8, wherein before forming the n-type GaN layer on the top ends of the protrusions and the un-doped GaN layer, a second un-doped GaN layer is formed on the top ends of the protrusions, then the n-type GaN layer, the active layer, and the p-type GaN layer are sequentially formed on the second un-doped GaN layer.
